(19) United States
(12) Patent Application Publication
(10) Pub. No.: US 2026/0248033 A1
(43) Pub. Date: Aug. 20, 2026

(54) SEMICONDUCTOR DEVICES HAVING DEEP TRENCH CAPACITORS AND METHODS OF FORMING THE SAME

(71) Applicant: Taiwan Semiconductor Manufacturing Company Limited, Hsinchu (TW)

(72) Inventors: Yi-Chen Li, Taichung City (TW); Jen-Yuan Chang, Hsinchu City (TW)

(21) Appl. No.: 19/053,542

(22) Filed: Feb. 14, 2025

(51) Int. Cl. H01L 25/18; H01L 23/00; H10D 1/00; H10D 1/68

(52) U.S. Cl. CPC H10W 90/00; H10D 1/042; H10D 1/714; H10D 1/716; H10W 90/792

(57) ABSTRACT

Semiconductor devices having deep trench capacitors and methods of fabricating the same. In some embodiments, a method includes forming a second passivation layer on a semiconductor die, the semiconductor die comprising redistribution layer (RDL) pads and a first passivation layer; forming a trench in the semiconductor die through the second passivation layer, between the redistribution pads, and into the first passivation layer; forming a deep trench capacitor within the trench by depositing a first electrode layer, a dielectric layer over the first electrode layer, and a second electrode layer over the dielectric layer; forming a third passivation layer over the deep trench capacitor; and forming at least one bond pad via (BPV) extending from the third passivation layer to a first one of the redistribution pads such that the BPV is electrically connected to the deep trench capacitor.

### BACKGROUND

An SoIC (System on Integrated Chips) inner die incorporating a Metal-Insulator-Metal (MIM) capacitor may serve as a core component in advanced semiconductor packaging. The inner die may feature multiple metal layers interconnected through vias, facilitating electrical connectivity across the die. A MIM capacitor may be integrated within the die structure, and the MIM capacitor may be formed by alternating dielectric material between two conductive metal electrodes. The MIM structure may provide high capacitance density while maintaining a small footprint, making it particularly useful for high-performance, space-constrained applications. MIM capacitors may be utilized for decoupling, noise reduction, and signal conditioning in RF circuits or mixed-signal environments. However, improvements to the resistance characteristics of related MIM capacitors to achieve improved capacitor efficiency are desired.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of an embodiment semiconductor device configured as a stacked die system.

FIG. 2 is a vertical cross-sectional detailed view of the second semiconductor die in a stacked die system according to an embodiment disclosed herein.

FIG. 3 is a vertical cross-sectional detailed view of the deep trench capacitor according to various embodiments disclosed herein.

FIG. 4 is a vertical cross-sectional detailed view that illustrates an alternative embodiment of the second semiconductor die in a stacked die system.

FIG. 5 is a vertical cross-sectional detailed view that illustrates an alternative embodiment of the second semiconductor die in a stacked die system.

FIG. 6 is a vertical cross-sectional detailed view that illustrates another embodiment of the second semiconductor die in a stacked die system.

FIGS. 7A and 7B are vertical cross-sectional detailed views that illustrate alternative embodiments of the second semiconductor die in a stacked die system.

FIGS. 8A and 8B are vertical cross-sectional detailed views that illustrate other embodiments of the second semiconductor die in a stacked die system.

FIGS. 9A-9K are vertical cross-sectional views illustrating example intermediate structures that may be formed during the process for forming the second semiconductor die according to various embodiments disclosed herein.

FIGS. 10A and 10B are top-down views of the second semiconductor die according to various embodiments disclosed herein.

FIG. 11 illustrates a flow diagram of an example method for fabricating a semiconductor device according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range. Various embodiments will be described in detail with reference to the accompanying drawings. Wherever possible, the same reference numbers will be used throughout the drawings to refer to the same or like parts. References made to particular examples and implementations are for illustrative purposes and are not intended to limit the scope of the claims.

The metal-insulator-metal (MIM) capacitor in some related System on Integrated Chip (SoIC) dies may be electrically coupled by way of redistribution pads as the circuit interconnect. Such related dies may use a bond pad via that establishes connections to the redistribution pads. However, such devices may suffer from the relatively high resistance of. Such increases in resistance may negatively impact the efficiency of the MIM capacitor. Additionally, the layout design of the capacitive region may need to account for the open areas of a passivation layer, further restricting its usable area.

Various embodiments disclosed herein are directed to SoIC source dies, inner dies, and other semiconductor devices that incorporate a deep trench capacitor structure passing between redistribution pads and through a multi-layered passivation structure. The deep trench capacitor may be useful, for example, in stabilizing a power supply voltage. The deep trench capacitor may have a large capacitance without interfering with underlying metal structures by passing between the redistribution pads.

An inner die may be a die that is located internally within the stacked configuration of the SoIC. In a multi-die stack, the inner die may be buried under one or more layers of other dies, with direct electrical and thermal connections to the surrounding dies or packaging layers. The “inner” designation generally distinguishes the inner die from an outer die, which may be positioned on the top or bottom layer of the stack.

A source die may be a die that provides a source of key functional elements such as power, signals, or data—that are used by other dies in the stack. A source die may be responsible for supplying resources (like power distribution or control signals) to the other dies, including the inner die.

One advantage of a deep trench capacitor as contrasted with a flat MIM capacitor is that deep trench capacitors may achieve greater values of capacitance while occupying a similar footprint of a semiconductor die. However, the utilization of such higher capacitance deep trench capacitors may benefit from their careful design and placement of within a semiconductor die to avoid interference with other structures formed within the semiconductor die as the deep trench capacitor may occupy more vertical space than a flat MIM capacitor.

In semiconductor dies that utilize MIM capacitors, the MIM circuit may be directly connected to a via through a bond pad via (BPV). Such direct connection may reduce interface resistance. In contrast to related SoICs that utilize flat, limited-depth MIM capacitors, the various embodiment SoIC dies that use deep trench capacitors may provide greater capacitance and lower resistance, which may improve the overall electrical performance of the dies. The various aspects of the present disclosure are now described with reference to various drawings of the present disclosure.

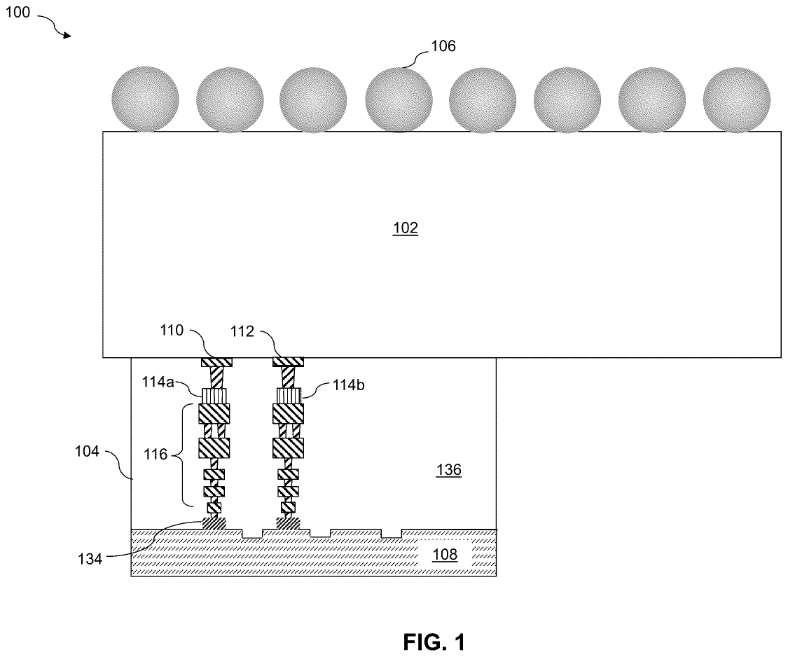

FIG. 1 is a vertical cross-sectional view of an embodiment semiconductor device 100 configured as a stacked die system. The semiconductor device 100 may be used as an SoIC system or part of an SoIC system. The semiconductor device 100 includes a first semiconductor die 102 stacked on a second semiconductor die 104. One or both of the first semiconductor die 102 and the second semiconductor die 104 may be a source die or inner die of an SoIC system.

The semiconductor device 100 includes at least one solder ball 106 for connecting the semiconductor device 100 to an external component (e.g., a printed circuit board (PCB) or interposer). The solder ball 106 may be used in flip-chip packaging or ball grid array (BGA) technology. The solder ball 106 may be made of a lead-free solder alloy and may serve as electrical connections between a die (or dies) and a package substrate or printed circuit board (PCB).

In some embodiments, the second semiconductor die 104 may include a substrate 108, a first bond pad via 110, a second bond pad via 112, redistribution layer (RDL) pads 114a, 114b, and interconnect structures 116 formed within dielectric layers 136. The substrate 108 may be formed from a semiconductor material such as silicon, silicon germanium, or gallium arsenide, depending on the performance requirements of the device. The substrate 108 serves as the foundational layer upon which other structures are fabricated. The redistribution layer (RDL) pads 114a, 114b may be formed from aluminum, and other conductive metal materials may be within the contemplated scope of disclosure. Using aluminum for the RDL pads 114a, 114b may be useful, for example, because aluminum exhibits good corrosion resistance, which may be beneficial for ensuring the long-term reliability of the exposed RDL pads 114a, 114b in packaging environments. Aluminum's lower cost as compared to copper may mean that aluminum is an economically advantageous choice for large-scale production. Moreover, aluminum pads may be less prone to electromigration at some current densities in RDL applications, further contributing to reliability. Aluminum's processing compatibility with silicon-based dielectrics and standard passivation layers may simplify fabrication of the RDL pads 114a, 114b, as it may not readily diffuse into silicon like copper, potentially reducing the need for diffusion barrier layers directly above the RDL pads 114a, 114b.

The first bond pad via 110 and the second bond pad via 112 may provide electrical conductivity between the interconnect structures 116 and the redistribution pads 114a, 114b and external circuits (e.g., circuits formed within the first semiconductor die 102). The first bond pad via 110 and the second bond pad via 112 may comprise conductive materials such as copper, tungsten, or aluminum. The first bond pad via 110 and the second bond pad via 112 may be formed, for example, using techniques such as damascene processes to ensure low resistance and high reliability.

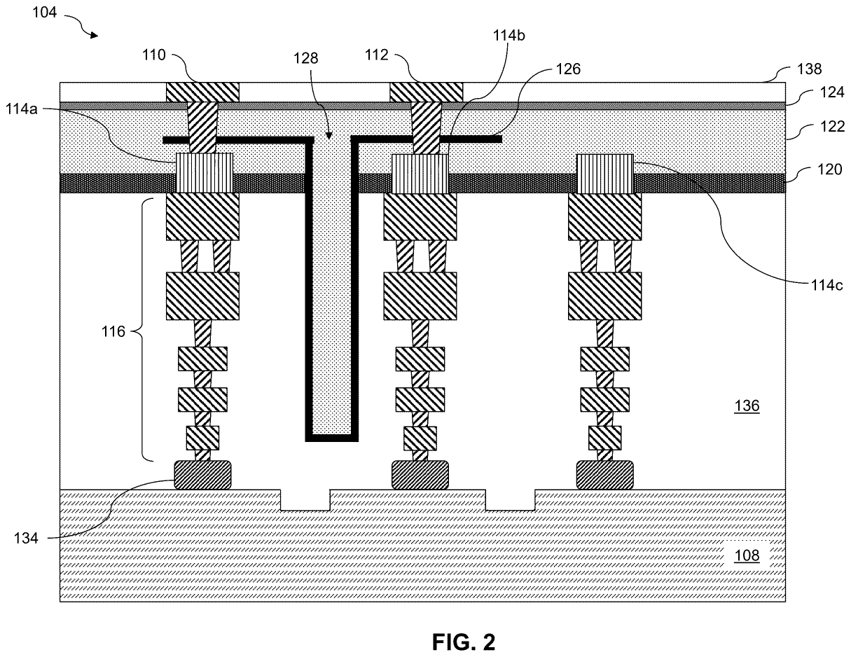

The redistribution pads 114a, 114b may be configured for routing of electrical signals (for example, electrical signals from the first bond pad via 110 and the second bond pad via 112) to different regions of the second semiconductor die 104. In some embodiments, the redistribution pads 114a, 114b may be possess advantages over pads made of metals such as copper due to aluminum's resistance to corrosion. The term “redistribution layer” is used herein to refer to the redistribution pads 114a, 114b and optionally to other dielectric layers and other conductive traces. For example, “redistribution layer” may refer to the redistribution pads 114a, 114b and the first passivation layer 120 (see e.g., FIG. 2).

The interconnect structures 116 may be formed of any appropriate conductive metal. In the embodiment shown in FIG. 1, the interconnect structures 116 and the first bond pad via 110 and the second bond pad via 112 may be formed of copper. Other conductive materials are within the contemplated scope of disclosure.

Aluminum may be used for the redistribution pads 114a, 114b, for example, because aluminum offers a balance of cost, adequate electrical performance, and ease of processing for wider traces, where lower resistivity may be less critical. Copper may be used for the interconnect structures 116, for example, because its superior conductivity, mechanical robustness, and ability to handle higher current densities may make it more suitable for the smaller cross-sectional areas involved in vertical structures such as vias.

The interconnect structures 116 may include a network of conductive paths within the second semiconductor die 104, which may directly connect transistors 134 and other circuit elements of the second semiconductor die 104. The interconnect structures 116 may include multiple metal layers separated by a number of dielectric layers 136 (e.g., silicon dioxide or silicon nitride), and the conductive paths may be formed using materials such as copper or aluminum. Other conductive materials are within the contemplated scope of disclosure. The interconnect structures 116 may be configured for transmitting signals, power, and ground connections across different components within the second semiconductor die 104. The fabrication of the interconnect structures 116 may include damascene or dual damascene processes and may include forming vias for vertical connections between layers.

The interconnect structures 116 may be patterned horizontally and vertically to connect to the first bond pad via 110 and the second bond pad via 112 and other components, and the interconnect structures 116 may be patterned while adhering to spacing rules to minimize parasitic effects. The interconnect structures 116 may include traces having a rectangular geometry that may be vertically integrated through multiple layers, for example, by vertical metal columns. The redistribution pads 114a, 114b may also have a rectangular geometry. The first bond pad via 110 and the second bond pad via 112 may have cylindrical or slightly tapered vertical geometries and, in some embodiments, may have rectangular tops, for example, to facilitate a wider area for connection to external components. The first bond pad via 110 and the second bond pad via 112 may be located adjacent to or directly beneath the redistribution pads 114a, 114b, and the first bond pad via 110 and the second bond pad via 112 may be symmetrically distributed, for example, to reduce the risk of electrical interference.

The first semiconductor die 102 may have any appropriate structure and, in the embodiment semiconductor device 100 shown in FIG. 1, may be electrically connected to the second semiconductor die 104 by the first bond pad via 110 and the second bond pad via 112. To simplify the drawings, various other components formed within the first semiconductor die 102 are not illustrated in detail.

In some embodiments, the first semiconductor die 102 and the second semiconductor die 104 may be bonded together using metal-to-metal bonding. As used herein, metal-to-metal bonding refers to the direct bonding of metal surfaces without the use of intermediate adhesives or solders. Metal-to-metal bonding may be provided through thermocompression bonding and/or diffusion bonding between two metallic surfaces that are in direct contact with each other by performing an anneal process at an elevated temperature. For example, bond pad vias corresponding to first bond pad via 110 and second bond pad via 112 may be formed within the first semiconductor die 102 and bonded to the first bond pad via 110 and second bond pad via 112 using metal-to-metal bonding.

FIG. 2 is a vertical cross-sectional detailed view of the second semiconductor die 104 according to some embodiments. The second semiconductor die 104 includes a first passivation layer 120, a second passivation layer 122 above the first passivation layer 120, and a third passivation layer 124 above the second passivation layer 122. The redistribution pads 114a-c may be positioned over the first passivation layer 120 and extend through the first passivation layer 120. The second semiconductor die 104 may include a long bonding film 138 over the third passivation layer 124, and the long bonding film 138 may include adhesive used to facilitate the mechanical connection between the second semiconductor die 104 and the first semiconductor die 102.

The second semiconductor die 104 may include a multilayer passivation structure, comprising the first passivation layer 120, second passivation layer 122, and third passivation layer 124, which are stacked sequentially. These passivation layers may be composed of dielectric materials such as silicon dioxide (SiO₂), silicon nitride (Si₃N₄), or polyimide. Other dielectric passivation materials are within the contemplated scope of disclosure. Each passivation layer may provide a protective function, preventing contamination and mechanical damage while also insulating the underlying circuit elements from external environmental factors, such as moisture or corrosive chemicals. The materials used for these layers may be selected based on their dielectric properties and their ability to withstand processing temperatures during subsequent fabrication steps.

In the embodiment illustrated in FIG. 2, the redistribution pads 114a-c may be formed such that they are positioned partially over the top surface of the first passivation layer 120 and extend through the first passivation layer 120 via etched openings, which allow direct contact with underlying structures. These openings may be formed through precision etching techniques, such as photolithography, laser drilling, and plasma etching.

The second passivation layer 122 and the third passivation layer 124 may be formed over the redistribution pads 114a-c to provide additional protection and insulation. The second passivation layer 122 and the third passivation layer 124 may mitigate against oxidation and mechanical wear on the redistribution pads 114a-c. Such protection may be useful for maintaining electrical performance and reliability over the operational life of the semiconductor die 104.

The thickness and material composition of each of the first passivation layer 120, the second passivation layer 122, and the third passivation layer 124 may vary depending on the specific application requirements, such as the need for flexibility in fan-out wafer-level packaging or the ability to withstand high-frequency signal transmission in RF applications. In some embodiments, the interfaces between the first passivation layer 120, the second passivation layer 122, and the third passivation layer 124 and the redistribution pads 114a-c may be designed and configured to minimize stress and thermal expansion mismatch, which could otherwise lead to delamination or cracking during thermal cycling.

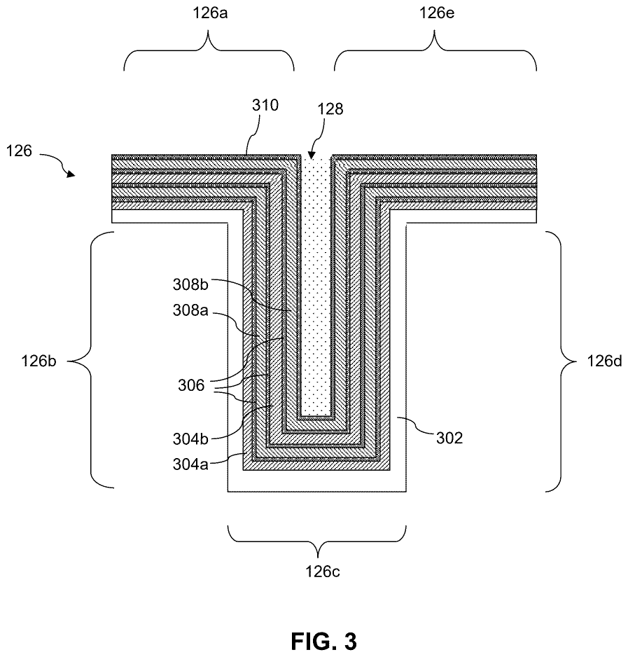

The second semiconductor die 104 may also include a deep trench capacitor 126. The deep trench capacitor 126 extends from the second passivation layer 122, between adjacent redistribution pads 114a, 114b, and through the first passivation layer 120. The shape and composition of the deep trench capacitor 126 are described in further detail with reference to FIG. 3, which shows that the deep trench capacitor 126 includes a first electrode layer 304a, a dielectric layer 306 over the first electrode layer 304a, and a second electrode layer 308a over the dielectric layer 306. Dielectric material fills a central gap 128 in the deep trench capacitor 126. The dielectric material that fills the central gap 128 may be the same or different material as the second passivation layer 122.

The third passivation layer 124 may be formed over the deep trench capacitor 126. One or both of the first bond pad via 110 and the second bond pad via 112 may extend from the third passivation layer 124 to the redistribution pads 114a, 114b. One or both of the first bond pad via 110 and the second bond pad via 112 may be electrically connected to the deep trench capacitor 126. For example, one or both of the first bond pad via 110 and the second bond pad via 112 may be electrically connected to the first electrode layer 304a or the second electrode layer 304b of the deep trench capacitor 126.

In the embodiment shown in FIG. 2, the deep trench capacitor 126 extends through the bottom of the first passivation layer 120, beyond the first passivation layer 120, and down into the dielectric layers 136 that have the interconnect structures 116 formed therein. The deep trench capacitor 126 may extend vertically downward to the bottom of the interconnect structures 116. The vertical depth of the deep trench capacitor 126 may vary to fit within an existing structure or to target a specific capacitance value.

FIG. 3 is a vertical cross-sectional view of the deep trench capacitor 126 according to some embodiments. The deep trench capacitor 126 includes a first horizontal section 126a extending from left to right, a first vertical section 126b extending downward, a second horizontal section 126c extending from left to right, a second vertical section 126d extending upward, and a third horizontal section 126e extending from left to right.

The deep trench capacitor 126 may include a dielectric liner 302. The dielectric liner 302 may include a dielectric material that provides electrical isolation between the deep trench capacitor 126 and any underlying structure (which may be different in embodiments having varying depths of the deep trench capacitor 126). For example, the dielectric liner 302 may include silicon oxide, silicon nitride, silicon oxynitride, and/or a dielectric metal oxide. Other suitable dielectric liner materials within the contemplated scope of disclosure may also be used. The thickness of the dielectric liner 302 may be in a range from 4 nm to 100 nm, although lesser and greater thicknesses may also be used.

An alternating layer stack of metallic electrode layers (304a, 308a, 304b, 308b) and node dielectric layers 306 may be formed by a respective conformal deposition process. The alternating layer stack includes at least three metallic electrode layers (e.g., 304a, 308a, 304b, 308b) interlaced with at least two node dielectric layers 306.

Each of the metallic electrode layers (304a, 308a, 304b, 308b) may include a metallic material, which may comprise, and/or consist essentially of, a conductive metallic nitride, an elemental metal, or an intermetallic alloy. In one embodiment, each metallic electrode layer (304a, 308a, 304b, 308b) comprises, and/or consists essentially of, a conductive metallic nitride material, which may be a metallic diffusion barrier material. For example, each metallic electrode layer (304a, 308a, 304b, 308b) may include, and/or may consist essentially of, a conductive metallic nitride material such as TiN, TaN, or WN. Other suitable materials within the contemplated scope of disclosure may also be used.

Use of a metallic diffusion barrier material for the metallic electrode layers (304a, 308a, 304b, 308b) may be advantageous because diffusion of metallic elements through the node dielectric layers 306 and/or through the dielectric liner 302 may cause deleterious effects for deep trench capacitors. Each metallic electrode layer (304a, 308a, 304b, 308b) may be formed by a conformal deposition process such as chemical vapor deposition (CVD) or atomic layer deposition (ALD). The thickness of each metallic electrode layer (304a, 308a, 304b, 308b) may be in a range from 5 nm to 50 nm, such as from 10 nm to 30 nm, although lesser and greater thicknesses may also be used. In one embodiment, each metallic electrode layer (304a, 308a, 304b, 308b) may have the same material composition and the same thickness. In another embodiment, each metallic electrode layer (304a, 308a, 304b, 308b) may have the same material composition but have varying thicknesses. In yet another embodiment, each metallic electrode layer (304a, 308a, 304b, 308b) may have different material composition and the same thickness. In yet another embodiment, each metallic electrode layer (304a, 308a, 304b, 308b) may have different material composition and different thicknesses.

Each of node dielectric layers 306 may include a node dielectric material, which may be a dielectric metal oxide material having a dielectric constant greater than 7.9 (which is the dielectric constant of silicon nitride), i.e., a “high-k” dielectric metal oxide material, or may include silicon nitride. For example, the node dielectric layer 306 may include a dielectric metal oxide material such as aluminum oxide, hafnium oxide, zirconium oxide, tantalum oxide, lanthanum oxide, an alloy or a silicate thereof, and/or a layer stack thereof. In one embodiment, the node dielectric layer 306 may include amorphous aluminum oxide layer that may be subsequently annealed into polycrystalline aluminum oxide material after formation of contact via structures. Other suitable materials within the contemplated scope of disclosure may also be used.

Each node dielectric layer 306 may be formed by a conformal deposition process such as chemical vapor deposition (CVD) or atomic layer deposition (ALD). The thickness of each node dielectric layer 306 may be in a range from 1 nm to 20 nm, such as from 3 nm to 12 nm, although lesser and greater thicknesses may also be used. In one embodiment, each node dielectric layer 306 may have the same material composition and the same thickness. In another embodiment, each node dielectric layer 306 may have the same material composition but have varying thicknesses. In yet another embodiment, each node dielectric layer 306 may have different material composition and the same thickness. In yet another embodiment, each node dielectric layer 306 may have different material composition and different thicknesses. For example, in an embodiment, a first node dielectric layer 306 may be thinner than a second node dielectric layer 306.

The total number of the metallic electrode layers (304a, 308a, 304b, 308b) may be in a range from 3 to 16, such as from 4 to 8. The total number of the node dielectric layers 306 may be one less than the total number of the metallic electrode layers (304a, 308a, 304b, 308b).

While the present disclosure is described using an embodiment in which the alternating layer stack of the metallic electrode layers (304a, 308a, 304b, 308b) and the node dielectric layers 306 include four metallic electrode layers (304a, 308a, 304b, 308b) and three node dielectric layers 306, embodiments are expressly contemplated herein in which different numbers of metallic electrode layers (304a, 308a, 304b, 308b) and different numbers of node dielectric layers 306 may be used within the alternating layer stack. Generally, an alternating layer stack may include at least three metallic electrode layers (304a, 308a, 304b, 308b) interlaced with at least two node dielectric layers 306.

The metallic electrode layers (304a, 308a, 304b, 308b) may be sequentially numbered in the order of deposition. For example, the metallic electrode layers (304a, 308a, 304b, 308b) may include a first metallic electrode layer 304a, a second metallic electrode layer 308a, a third metallic electrode layer 304b, a fourth metallic electrode layer 308b, etc. Patterned portions of each odd-numbered metallic electrode layer (304a, 304b) may be subsequently used to form a primary electrode assembly that functions as a primary node, i.e., a first node, of the deep trench capacitor 126, and patterned portions of each even-numbered metallic electrode layer (308a, 308b) may be subsequently used to form a complementary electrode assembly that functions as a complementary node, i.e., a second node, of the deep trench capacitor 126. The total number of the metallic electrode layers (304a, 308a, 304b, 308b), the thicknesses of the metallic electrode layers (304a, 308a, 304b, 308b), and the width of the horizontal section 126c may be selected such that a predominant portion (i.e., more than 50%) of the entire volume of the deep trench capacitor 126 may be filled with the alternating layer stack without completely filling the space between the vertical sections 126b, 126d of the deep trench capacitor 126. For example, a central gap 128 may remain.

A capping dielectric material layer 310 and a dielectric fill material layer (within central gap 128) may be optionally deposited over the alternating layer stack. The capping dielectric material layer 310 may include a same dielectric material as the node dielectric layers 306 and may have a thickness in a range from 1 nm to 20 nm, such as from 3 nm to 12 nm, although lesser and greater thicknesses may also be used.

The dielectric fill material layer may be deposited on the capping dielectric material layer 310 or on the alternating layer stack to fill the volumes of the central gap 128 that remains between the vertical sections 126b, 126d of the deep trench capacitor 126. In one embodiment, the dielectric fill material layer comprises, and/or consists essentially of, undoped silicate glass or a doped silicate glass. In some embodiments, the dielectric fill material layer that fills the central gap 128 may be the same material as the second passivation layer 122. In other embodiments, the dielectric fill material layer that fills the central gap 128 may be a different material as the second passivation layer 122.

MIM (Metal-Insulator-Metal) capacitors, such as the deep trench capacitor 126 described here, rely on the arrangement of conductive and dielectric layers to achieve the desired capacitance values. These layers may be engineered to realize a target electrical performance, and their material composition, thickness, and layout determine the overall capacitance and electrical characteristics.

The choice of electrode material may be based on design targets for minimizing losses and ensuring efficient signal transmission, particularly in high-frequency applications. Copper may be selected for its superior electrical conductivity, while aluminum may be selected for its lower cost and ease of integration with standard semiconductor processes.

The dielectric layers 306 may be positioned between the electrode layers (304a, 308a, 304b, 308b) and serves as the insulating material. The purpose of dielectric layers 306 is to store electrical energy when a potential difference is applied across the electrodes. The dielectric material may be selected from a variety of materials, depending on the application requirements. High-k dielectric materials, such as hafnium oxide (HfO₂), silicon dioxide (SiO₂), or silicon nitride (Si₃N₄), may be used to increase capacitance by allowing greater charge storage without significantly increasing the physical size of the deep trench capacitor 126.

The configuration of the deep trench capacitor 126 allows for flexible tuning of the capacitor's electrical characteristics. Different combinations of materials and layer thicknesses may be employed to optimize the performance for specific applications, such as high-frequency signal filtering, power supply decoupling, or energy storage.

By adjusting the dielectric constant and trench depth, a designer may maximize capacitance density. High-k dielectrics in conjunction with deep trench structures may result in very high capacitance per unit area, which may be particularly useful in space-constrained designs like system-on-chip (SoC), 3D-stacked integrated circuits (ICs), and SoICs.

The thickness of the dielectric layer 306 and the material composition of the dielectric layer 306 may also affect the breakdown voltage and leakage current of the deep trench capacitor 126. Thicker dielectrics may offer better voltage handling but lower capacitance, while thinner layers may store more charge but may suffer from increased leakage currents or breakdown at high voltages. For applications requiring high reliability, such as automotive or aerospace systems, careful selection of the dielectric thickness and material may be useful for ensuring long-term stability.

The material properties and thickness of the dielectric layers 306 and electrode layers (304a, 308a, 304b, 308b) may influence the frequency response of the deep trench capacitor 126. For high-frequency applications, materials with low dielectric loss and low series resistance may be employed to reduce or minimize signal degradation and ensure stable capacitance across a wide range of operating frequencies. The choice of copper for the electrode layers (304a, 308a, 304b, 308b), for example, may reduce skin effect losses in RF applications, improving overall performance.

The arrangement of the MIM layers may also be designed to facilitate low series resistance and minimize parasitic capacitance, enhancing the efficiency and response time of the deep trench capacitor 126. As a result, using multiple MIM layers in the deep trench capacitor 126 provides advantages in applications where high capacitance density and miniaturization are essential, such as in high-performance integrated circuits and advanced packaging technologies.

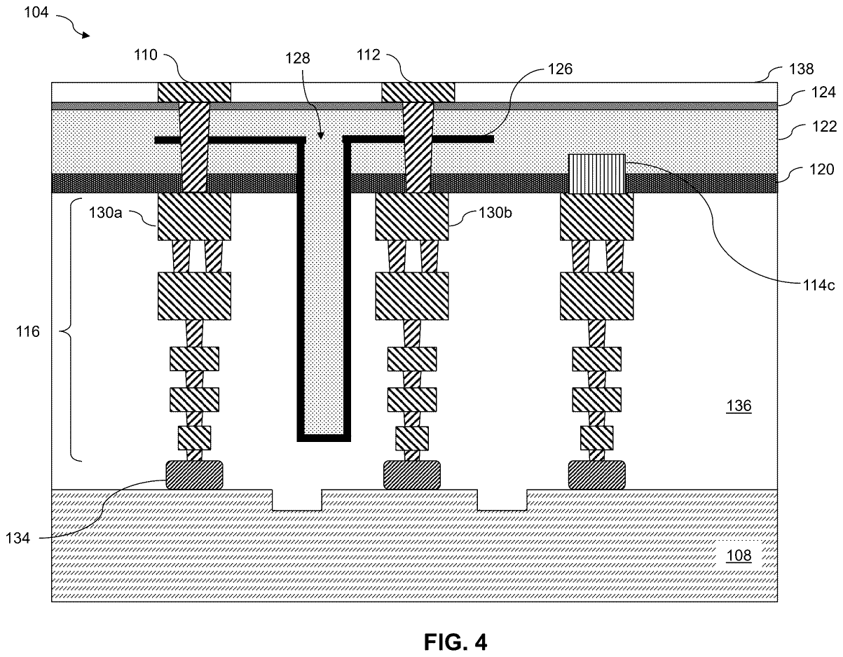

FIG. 4 is a vertical cross-sectional view that illustrates an alternative embodiment of the second semiconductor die 104 where the first bond pad via 110 and the second bond pad via 112 extend vertically downward through the second passivation layer 122 and the first passivation layer 120 to electrically connect to top metal pads 130a, 130b of the interconnect structures 116. The deep trench capacitor 126 extends vertically downward between adjacent top metal pads 130a, 130b.

In this embodiment, the first bond pad via 110 and the second bond pad via 112 omit the first redistribution pad 114a or the second redistribution pad 114b of the embodiment illustrated in FIG. 2. This configuration may allow for greater flexibility in the placement and routing of interconnects, especially in regions in which the redistribution pads 114a, 114b are intentionally absent due to design constraints or functional requirements.

The first bond pad via 110 and the second bond pad via 112, which may be composed of a highly conductive material such as copper, tungsten, or aluminum, may be formed using etching and deposition techniques. The use of the first bond pad via 110 and the second bond pad via 112 to directly interface with the interconnect structures 116 may reduce or eliminate reliance on the redistribution pads 114a, 114b in certain areas, allowing for low resistance signal routing and reduced parasitic resistance and capacitance. This may be particularly beneficial in high-speed or high-frequency circuits, where minimizing these parasitic effects may be useful for maintaining signal integrity.

The top metal pads 130a, 130b within the interconnect structures 116 comprise a conductive material, such as copper or aluminum. By directly connecting the first bond pad via 110 and the second bond pad via 112 to the top metal pads 130a, 130b, this embodiment may reduce the number of intermediary layers that signals must traverse, which may in turn reduce signal delay and improve overall electrical performance.

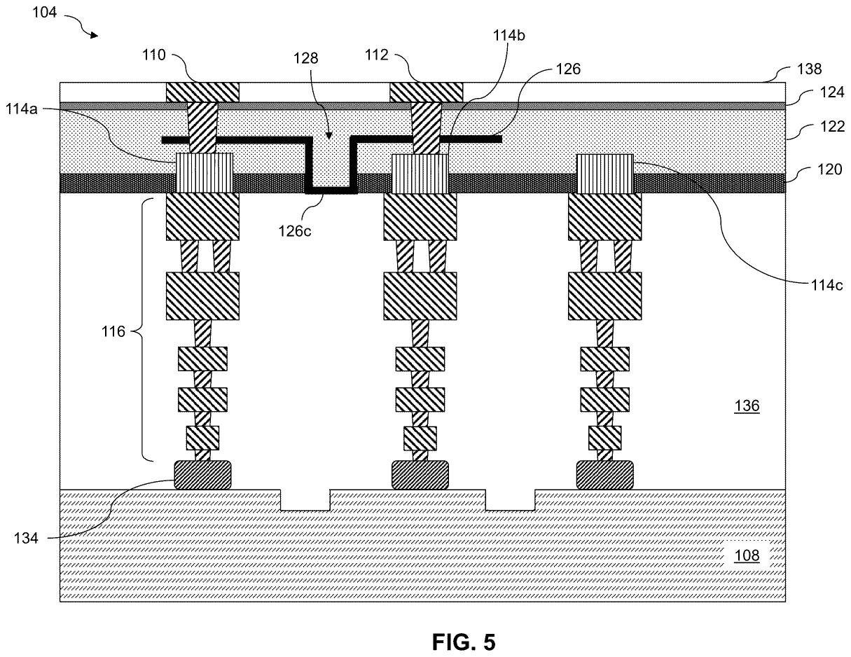

FIG. 5 is a vertical cross-sectional view that illustrates an alternative embodiment of the second semiconductor die 104 in which the deep trench capacitor 126 extends vertically downward through the first passivation layer 120 to a depth where the lowest horizontal section 126c of the deep trench capacitor 126 is co-planar with the bottom of the first passivation layer 120 at the interface with the dielectric layers 136 surrounding the interconnect structures 116. This configuration may be particularly beneficial in scenarios where a smaller capacitance value is acceptable and there is a need to preserve the integrity and layout of the top metal layer of the interconnect structures 116.

By minimizing the depth of the deep trench capacitor 126, the alternative embodiment may avoid interference with the routing of the interconnect structures 116. This may be beneficial as the interconnect structures 116 may contain key signal pathways or power distribution networks. The configuration of this alternative embodiment may be advantageous in applications in which minimizing parasitic interactions with the interconnect structures 116 is a priority, such as in high-speed digital circuits or sensitive analog environments. By configuring the deep trench capacitor 126 such that the deep trench capacitor 126 does not interfere with the various metal lines and vias of the interconnect structures 116, a desired capacitance may be provided without impacting the design and configuration of the interconnect structures 116.

The embodiment illustrated in FIG. 5 may be useful in designs where a balance between performance and die space utilization is required. The shorter trench depth reduces the overall capacitance as compared to the embodiment in FIG. 2, where the deep trench capacitor 126 extends further. However, in applications where the desired capacitance is lower, such a design tradeoff may be acceptable. Moreover, the embodiment design may achieve the desired benefits such as reduced trench etching complexity and improved layout flexibility. In embodiments in which the deep trench capacitor 126 does not penetrate the dielectric layers 136 surrounding the interconnect structures 116, the designer may have more freedom in routing signal lines, power distribution, or other interconnect features without being constrained by the physical presence of the deep trench capacitor 126.

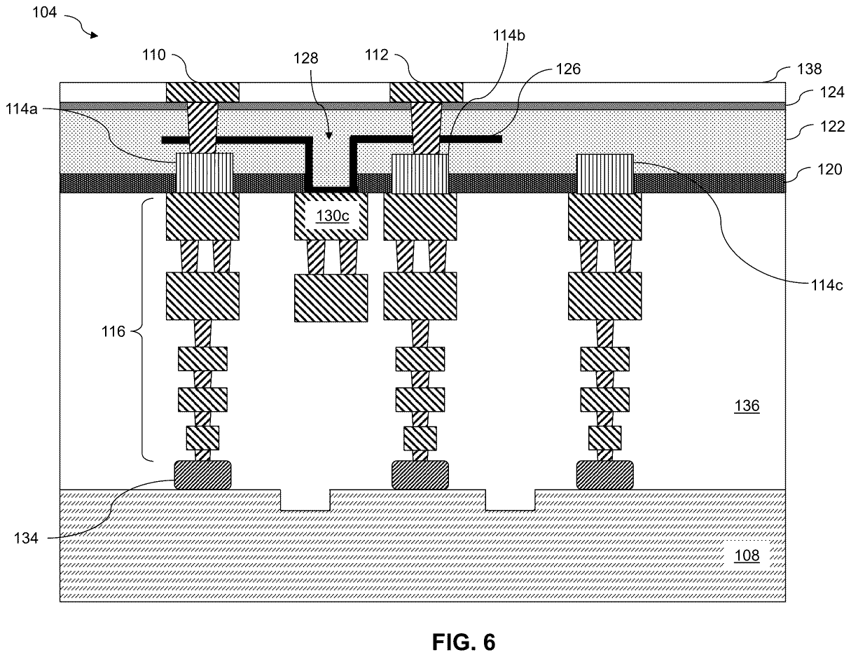

FIG. 6 is a vertical cross-sectional view that illustrates another embodiment of the second semiconductor die 104 in which the deep trench capacitor 126 extends vertically downward through the first passivation layer 120 and contacts a top metal pad 130c. In some embodiments, the first electrode layer (e.g., electrode layer 304a) of the deep trench capacitor 126 may be electrically connected to the top metal pad 130c. Such a configuration may be useful, for example, in which the capacitance of the deep trench capacitor 126 is desired within the electrical circuit connected to the top metal pad 130c.

In this embodiment, the electrical connection to the top metal pad 130c may enable the deep trench capacitor 126 to influence circuit parameters such as filtering, decoupling, or energy storage. For instance, this configuration may be particularly beneficial in power management applications where the deep trench capacitor 126 can help stabilize voltage levels by quickly supplying or absorbing charge, thereby improving overall circuit performance.

Moreover, the integration of the deep trench capacitor 126 with the top metal pad 130c may allow for a reduced interconnect length, minimizing parasitic inductance and resistance that may degrade the performance of the deep trench capacitor 126. This may be particularly useful in high-frequency applications where swift voltage changes occur, and any additional resistance or inductance could adversely affect signal integrity.

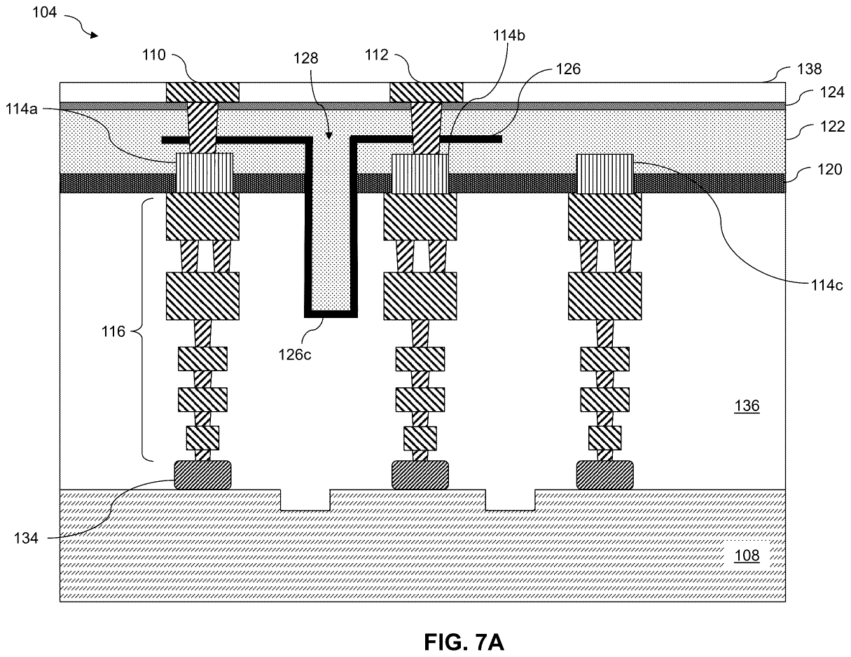

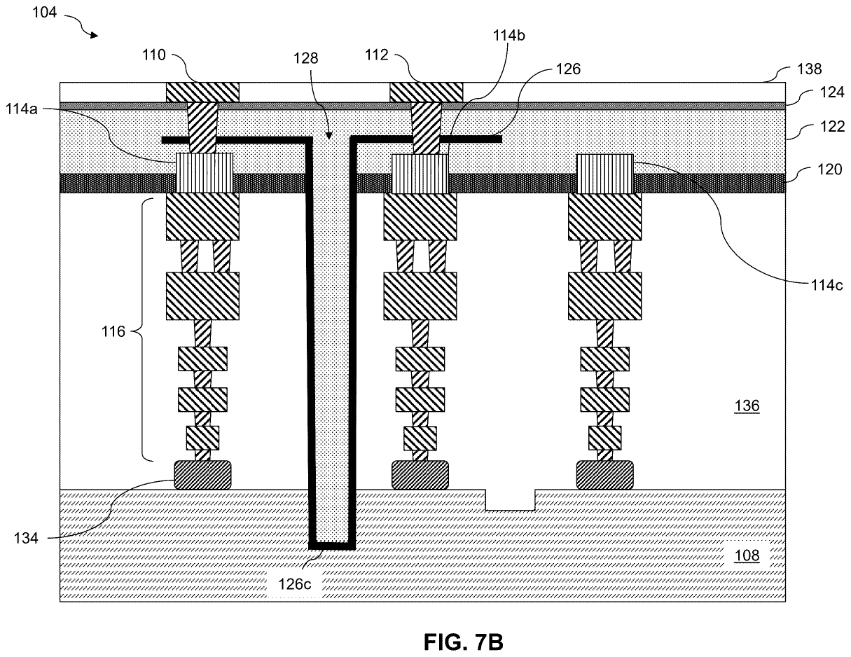

FIG. 7A is a vertical cross-sectional view that illustrates an alternative embodiment of the second semiconductor die 104 in which the deep trench capacitor 126 may extend vertically downward through the first passivation layer 120 and into the dielectric layers 136 and past the top metal pads 130a-c but does not reach the substrate 108 or the bottom of the interconnect structures 116. Instead, the deep trench capacitor 126 extends vertically downward to an intermediate depth in the dielectric layers 136 surrounding the interconnect structures 116.

For example, the deep trench capacitor 126 may extend vertically downward past two or more metal layers of the interconnect structures 116, or the deep trench capacitor 126 may extend vertically downward a quarter, a third, a half, two thirds, or three-quarters of the way along the interconnect structures 116. This may be useful, for example, in which the intermediate depth allows for the deep trench capacitor 126 to provide sufficient capacitance to meet design targets for electrical performance. Such a capacitance may be greater than the capacitance provided with the deep trench capacitor 126 of the embodiment illustrated in FIG. 5 or 6.

FIG. 7B is a vertical cross-sectional view that illustrates an alternative embodiment of the second semiconductor die 104 in which the deep trench capacitor 126 extends vertically downward through the first passivation layer 120, through the dielectric layers 136 and the into the substrate 108. An anisotropic etch process may be performed to transfer a pattern in a patterned etch mask layer through an upper portion of the substrate 108 to form the trench in the substrate 108 reached by the lowest horizontal section 126c of the deep trench capacitor 126. This embodiment may be particularly useful, for example, for designs calling for a large capacitance value.

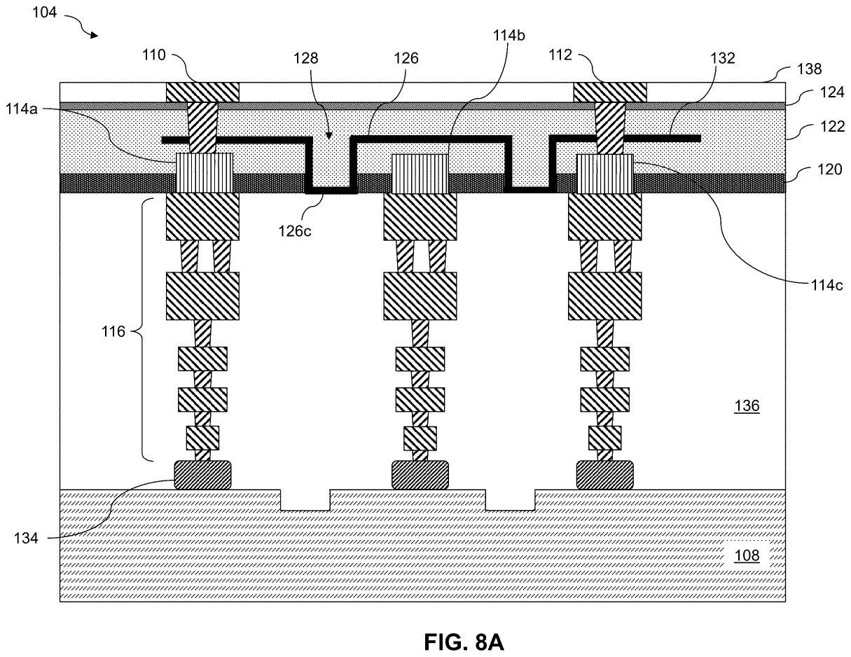

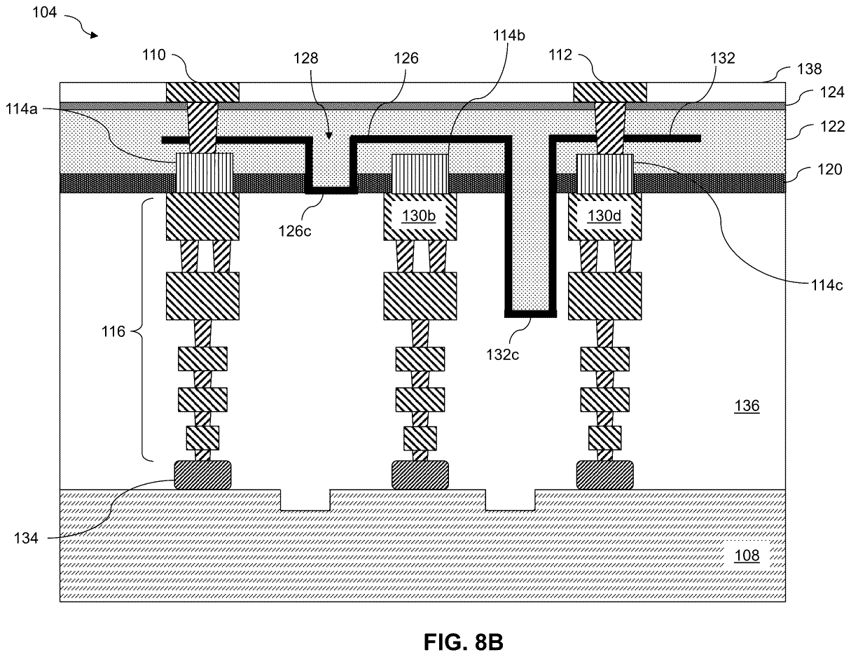

FIG. 8A is a vertical cross-sectional view that illustrates another embodiment of the second semiconductor die 104 in which the deep trench capacitor 126 is electrically connected to a horizontally adjacent deep trench capacitor 132. Both the deep trench capacitor 126 and the adjacent deep trench capacitor 132 extend vertically downward through the first passivation layer 120.

The vertical portions of the deep trench capacitor 126 may be positioned between the first redistribution pad 114a and the second redistribution pad 114b. The vertical portions of the adjacent deep trench capacitor 132 may be positioned between the second redistribution pad 114b and a third redistribution pad 114c. In this manner, the deep trench capacitor 126 and the adjacent deep trench capacitor 132 may fit between three redistribution pads 114a-c and three interconnect structures 116.

The first bond pad via 110 and the second bond pad via 112 may be electrically connected to each other by way of the deep trench capacitor 126 and the adjacent deep trench capacitor 132 to form a capacitive circuit. This may be useful, for example, where a particularly high total capacitance is desired. For example a first electrode layer 304a may be coupled to the first bond pad via 110 and the second electrode layer 308b may be coupled to the second bond pad via 112.

The arrangement of multiple deep trench capacitors (i.e., the deep trench capacitors 126 and the adjacent deep trench capacitor 132) within the semiconductor die 104 contributes to enhanced capacitance without necessitating larger die dimensions. By leveraging advanced materials and manufacturing techniques, such as atomic layer deposition (ALD) for thin dielectric layers, the deep trench capacitor 126 and adjacent deep trench capacitor 132 may achieve high performance in terms of leakage current and dielectric breakdown voltage. The overall capacitance can be tailored by adjusting the number of MIM layers, the dielectric constants of the materials used, and the geometrical configuration of the deep trenches.

Additionally, the proximity of these capacitors may facilitate faster charge and discharge cycles, resulting in improved transient response characteristics. This may be useful, for example, in high-frequency applications where rapid voltage changes are required, such as in decoupling capacitors for integrated circuits. The use of horizontally adjacent deep trench capacitors also aids in thermal management, as the arrangement can help dissipate heat more evenly across the die, contributing to overall reliability and performance of the semiconductor device.

FIG. 8B is a vertical cross-sectional view that illustrates another embodiment of the second semiconductor die 104 where the deep trench capacitor 126 and the adjacent deep trench capacitor 132 extend vertically downward to different depths. The lowest horizontal section 126c of the deep trench capacitor 126 is at a depth of the bottom of the first passivation layer 120. The lowest horizontal portion 132c of the adjacent deep trench capacitor 132 is a depth below the first passivation layer 120 and below the top metal pads 130b and 130d. This embodiment may be useful, for example, in creating a specific capacitance value that arises from this combination of deep trench capacitors 126 and 132. A disadvantage may be the increased manufacturing complexity that arises in creating trenches at two different depths.

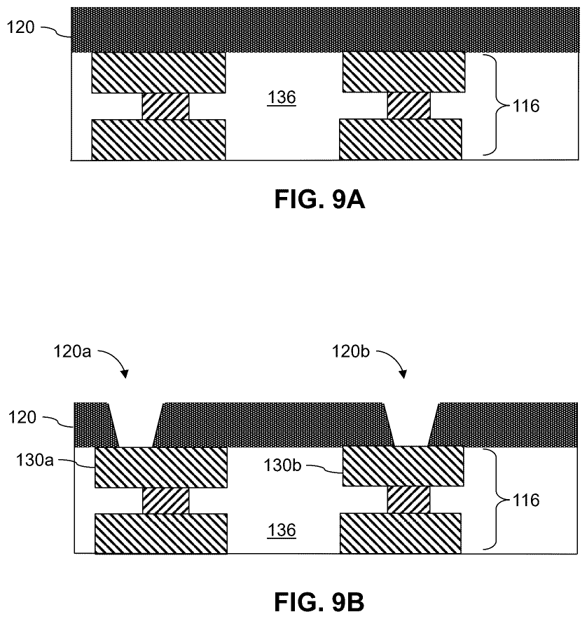

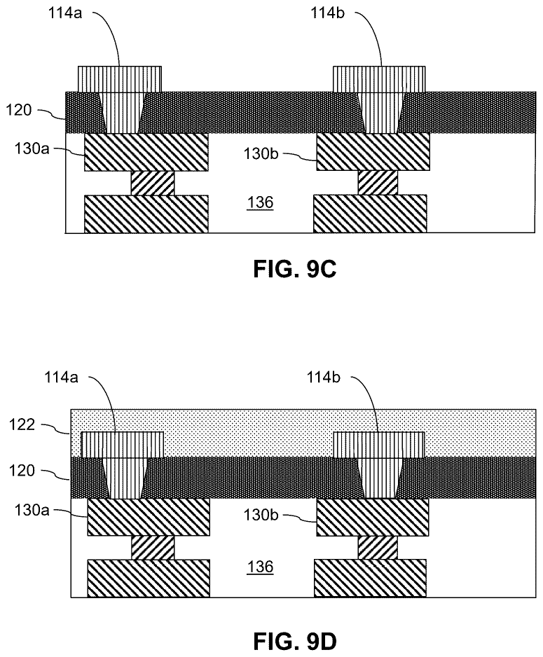

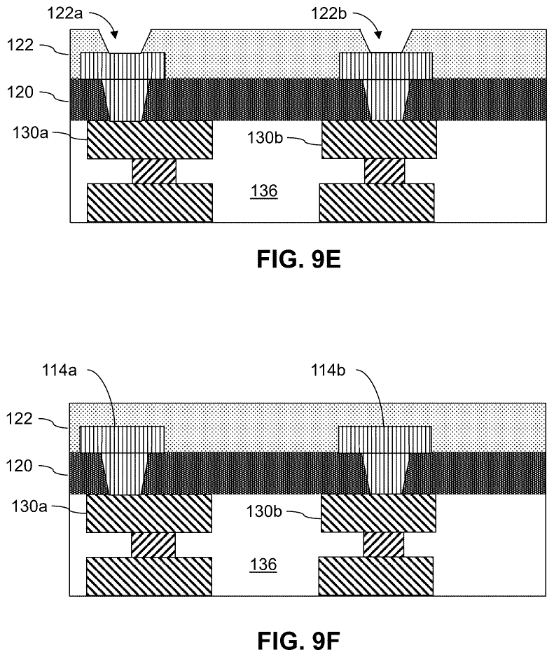

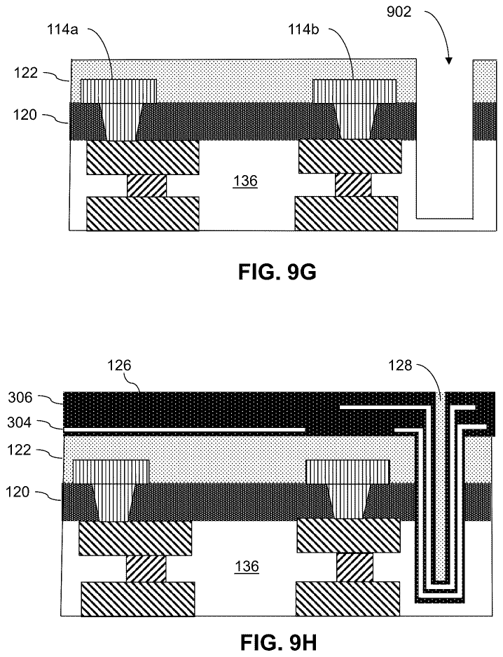

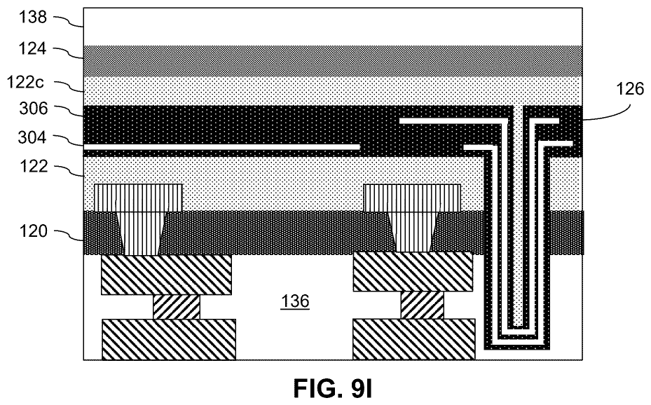

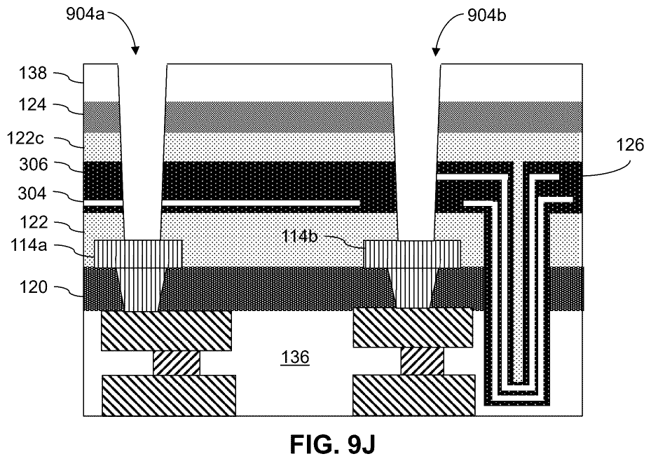

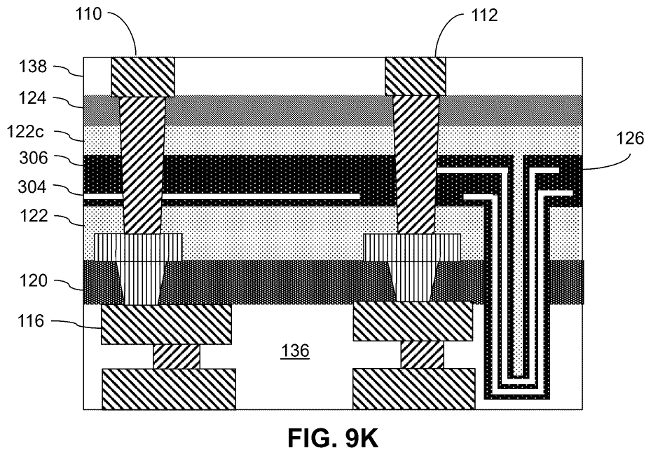

FIGS. 9A-9K are vertical cross-sectional views illustrating example intermediate structures that may be formed during the process for forming the second semiconductor die 104.

FIG. 9A shows the first passivation layer 120 being formed over the interconnect structures 116 and the dielectric layers 136 having the interconnect structures 116 formed therein. The first passivation layer 120 may be formed, for example, by chemical vapor deposition.

FIG. 9B illustrate openings 120a and 120b being formed in the first passivation layer 120. The openings 120a and 120b may extend through the first passivation layer 120 to the top metal pads 130a, 130b, respectively. The openings 120a and 120b may be formed, for example, by lithographic patterning and etching.

FIG. 9C illustrate redistribution pads 114a and 114b being formed in the openings 120a and 120b, respectively. Other RDL traces (not shown) may be formed of aluminum to define an RDL pattern over the semiconductor die 104.

FIG. 9D illustrates the second passivation layer 122 being formed over the redistribution pads 114a, 114b and the first passivation layer 120. The second passivation layer 122 may be formed, for example, by chemical vapor deposition.

FIG. 9E illustrates optional openings 122a and 122b being formed in the second passivation layer 122. The openings 122a and 122b each extend through the second passivation layer 122 to the redistribution pads 114a and 114b, respectively. The openings 122a and 122b may be formed, for example, by patterning and etching, and the openings 122a and 122b may be used for electrical testing of the redistribution pads 114a and 114b. For example, electrical testing may include contact probing of the redistribution pads 114a and 114b and wafer acceptance testing.

FIG. 9F illustrates the optional openings 122a and 122b being filled with dielectric material after electrical testing, restoring the second passivation layer 122. For example, a gap filling process may be performed to fill the openings 122a and 122b. Planarization may be performed to flatten the top surface of the second passivation layer 122, for example, after the openings 122a, 122b are filled. The second passivation layer 122 may be flattened, for example, by chemical mechanical planarization (CMP).

FIG. 9G illustrates a trench 902 being defined through the second passivation layer 122, the first passivation layer 120, and into the dielectric layers 136 having the interconnect structures 116 formed therein to a target depth. The trench 902 may be defined by lithography and etching processes.

In some embodiments, the first step in defining the trench 902 is lithography, in which a pattern is transferred onto the surface of the planarized second passivation layer 122. The process begins with the application of a photoresist layer, which is a light-sensitive material, over the surface of the second passivation layer 122. A mask with the desired trench pattern is then aligned with the intermediate structure, and ultraviolet (UV) light is used to expose the photoresist. In regions exposed to the UV light, the photoresist undergoes a chemical change, allowing it to be selectively removed during the development process, leaving behind the desired pattern.

After the trench pattern is defined in the photoresist, the trench 902 is formed through an etching process. The etching may be performed using dry etching techniques, such as reactive ion etching (RIE), or wet etching, depending on the materials and the desired trench profile.

In RIE, plasma containing reactive ions is used to etch away the exposed portions of the second passivation layer 122 and the underlying first passivation layer 120. RIE provides highly anisotropic etching, which means that it etches vertically downward with minimal lateral etching. This may be useful for creating precise, well-defined trenches with vertical sidewalls, ensuring that the trench 902 has the correct depth and shape.

In some embodiments, wet etching may be used, particularly for materials that are more easily etched by chemical reactions in liquid solutions. Wet etching, however, is more isotropic and may result in more rounded or sloped trench profiles.

The trench may be is etched to a specific target depth, which is selected for the intended application. The trench 902 extends through the second passivation layer 122 and the first passivation layer 120. The depth of the trench 902 may be carefully controlled to ensure proper contact with the target location in the dielectric layers 136, without over-etching, which may damage underlying structures or compromise the integrity of the interconnect structures 116. For example, the trench 902 may have a width of at least 1 nm and, in some embodiments, great than 50 nm. The trench 902 may have a depth of at least 1 nm and less than or equal to 5 μm.

FIG. 9H illustrates the dielectric layers 306 and electrode layers 304 being deposited over the second passivation layer 122 and into the trench 902 to form the deep trench capacitor 126. The central gap 128 between the vertical portions of the deep trench capacitor 126 may be subsequently filled with dielectric material. The top surface of the intermediate structure may be planarized, for example, using chemical mechanical planarization.

The deep trench capacitor 126 includes electrode layers 304, which may be deposited along the vertical sidewalls of the trench. These electrode layers can be formed using a range of conductive materials, such as aluminum (Al), copper (Cu), or other highly conductive metals.

The deposition of the electrode layers may occur through methods such as physical vapor deposition (PVD) or atomic layer deposition (ALD), depending on the required thickness and uniformity of the layers. In PVD, metal atoms are sputtered onto the surface of the trench 902, adhering to the sidewalls, while ALD offers highly controlled, conformal layer deposition, which may be useful in deep trench geometries where uniformity is useful for reliable capacitor performance.

The dielectric layer 306 may be deposited with high precision to ensure uniform coverage of the trench sidewalls, as variations in thickness may lead to non-uniform capacitance values across the structure. The thickness of the dielectric layer 306 may directly affect the capacitance of the deep trench capacitor 126. A thinner dielectric layer 306 increases capacitance but may increase the risk of dielectric breakdown. ALD may be used for the dielectric layer 306, particularly for high-k materials, providing precise control over the thickness and uniformity of the dielectric film even in the constrained geometry of the trench 902.

Once the electrode layers 304 and the dielectric layer 306 of the deep trench capacitor 126 are deposited along the vertical sidewalls and bottom of the trench 902, the central gap 128 between the vertical portions of the capacitor may be filled with a dielectric material. This central gap-filling process may be useful to ensure that the trench 902 is completely insulated and that no air voids or mechanical gaps exist that could degrade the performance or structural integrity of the deep trench capacitor 126. The central gap 128 may be filled using a dielectric material that is the same as the second passivation layer 122.

The dielectric filling process may be controlled to avoid voids or defects that could lead to poor electrical insulation or mechanical weakness in the final structure. For example, the filling may be achieved using chemical vapor deposition (CVD), which allows the dielectric material to flow into the gap and fully occupy the available space. For particularly narrow or deep trenches, conformal deposition techniques like ALD may be employed to ensure complete coverage and filling of the trench without leaving voids or gaps.

FIG. 9I illustrates a third passivation layer 124 after being deposited over the second passivation layer 122 and the deep trench capacitor 126. The long bonding film 138 may be formed over the third passivation layer 124, for example, to facilitate bonding to the first semiconductor die 102 of FIG. 1. In some embodiments, the gap filling process that fills the central gap 128 of the deep trench capacitor 126 may also include depositing a covering dielectric layer 122c over the top of the deep trench capacitor 126 using the same dielectric material used to fill the central gap 128. The dielectric material used to fill the central gap 128 and create the covering dielectric layer 122c may be the same dielectric material used for the second passivation layer 122.

FIG. 9J illustrates cavities 904a and 904b formed in the intermediate structure in which bond pad vias 110 and 112 may be subsequently formed. In some embodiments, the cavities 904a and 904b may be created by lithography and etching processes, and the cavities 904a and 904b may extend vertically from the long bonding film 138 to the redistribution pads 114a and 114b.

FIG. 9K illustrates the bond pad vias 110 and 112 formed in the cavities 904a and 904b, respectively. The cavities 904a and 904b may be filled with any appropriate conductive material to form the bond pad vias 110 and 112, respectively. For example, a barrier layer may be deposited in the cavities 904a and 904b and then copper may be electroplated within the cavities 904a and 904b. In some embodiments, the top surface of the structure is then flattened, for example, using chemical mechanical planarization.

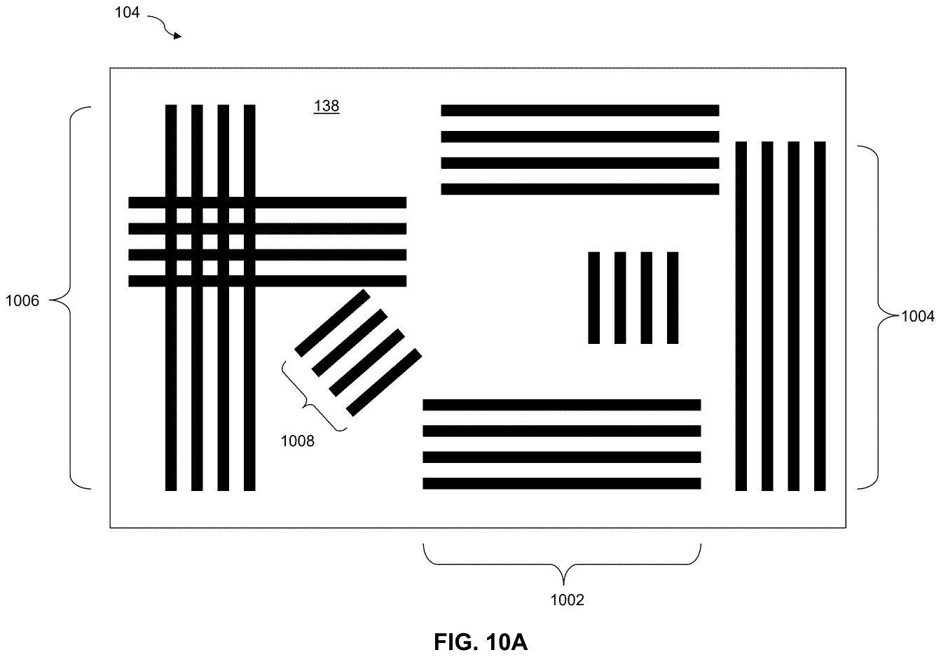

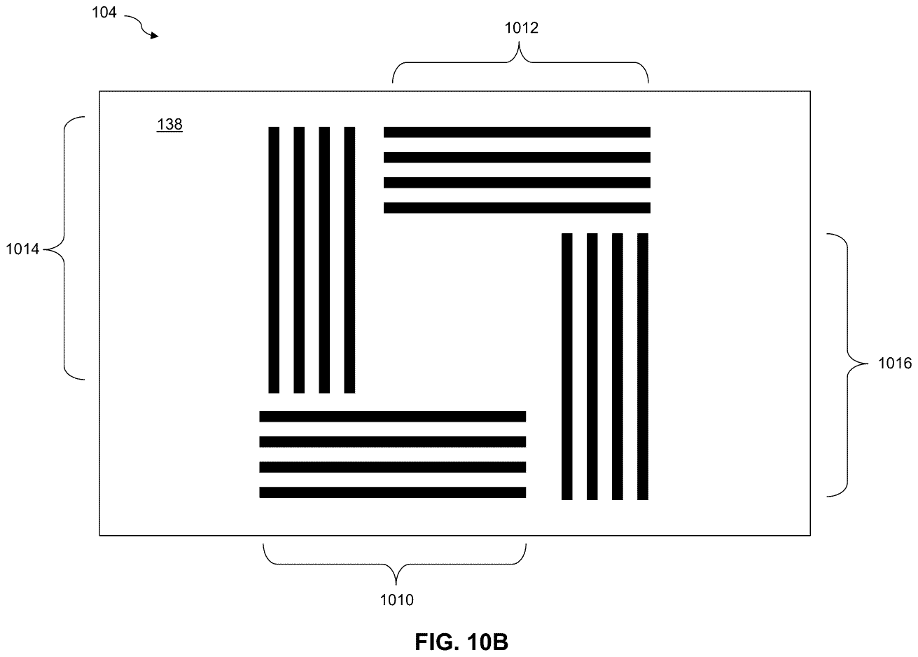

FIGS. 10A-10B are top-down see-through views of the second semiconductor die 104 according to some embodiments. Various deep trench capacitors are illustrated to show groupings and orientations of deep trench capacitors even though the view of the deep trench capacitors would normally be obstructed by the long bonding film 138. Views of the bond pad vias are omitted for the purpose of simplifying the drawings.

FIG. 10A is a top down view illustrating an embodiment of the second semiconductor die 104 having a group of horizontal trench capacitors 1002 and a group of longitudinal trench capacitors 1004. Each of the horizontal trench capacitors 1002 extends vertically downward (into the page) through the second passivation layer 122, between respective redistribution pads and in some embodiments into the first passivation layer 120. Each of the longitudinal trench capacitors 1004 extends vertically downward (into the page) from the second passivation layer 122, between respective redistribution pads, and into the first passivation layer 120.

In some embodiments, trench capacitors oriented in two or more different directions may be electrically connected. For example, FIG. 10A shows a group of both longitudinal and horizontal deep trench capacitors 1006 that are electrically connected to each other. In general, the second semiconductor die 104 may include deep trench capacitors 126 with any appropriate combination of different orientations. In some embodiments, the second semiconductor die 104 includes a group of oblique deep trench capacitors 1008 that are oblique at an angle between the longitudinal direction and the horizontal direction. In some embodiments, each deep trench capacitor is spaced apart from any other deep trench capacitor by at least 5 μm, for example, to avoid parasitic capacitance effects.

The orientations of the trench capacitors may be positioned for warpage control of the second semiconductor die 104. FIG. 10B shows an embodiment of the second semiconductor die 104 having a first group of horizontal deep trench capacitors 1010, a second group of horizontal deep trench capacitors 1012, a first group of longitudinal deep trench capacitors 1014, and a second group of longitudinal deep trench capacitors 1016.

To reduce or prevent warpage potentially caused by defining trenches, the lengths and orientations of the deep trench capacitors may be positioned such that a difference between a total length of all of the longitudinal trench capacitors (the first group of longitudinal deep trench capacitors 1014 plus the second group of longitudinal deep trench capacitors 1016) and a total length of all of the horizontal trench capacitors (the first group of horizontal trench capacitors 1010 plus the first group of horizontal trench capacitors 1012) is less than 25% as a relative difference between the total lengths of the longitudinal trench capacitors 1014 and 1016 and the horizontal trench capacitors 1010 and 1012, normalized to the total length of one set of capacitors (for example, the longer set).

Instead of expressing the absolute difference in units of length, the 25% figure provides a way to express the relative imbalance between the two orientations of capacitors. This allows the rule to be applicable regardless of the total size of the second semiconductor die 104 or the capacitors. For example, in embodiments in which the total length of all longitudinal trench capacitors 1014 and 1016 is significantly larger than that of the horizontal trench capacitors 1010 and 1012, it may create an asymmetric distribution of material, leading to greater mechanical stress and potential warpage. By capping the difference to less than 25%, structural balance may be maintained.

For example, the percentage difference may be determined by:

$$\frac{( \vert {L}_{longitudinal} - {L}_{horizontal} \vert )}{max ( {L}_{longitudinal} , {L}_{horizontal} )} * 100 \%$$

Where L_{longitudinal} and L_{horizontal} are the total lengths of the longitudinal and horizontal trench capacitors, respectively. In embodiments in which the ratio value is less than 25%, the ratio value satisfies the condition. This may ensure that the relative difference remains within a manageable range for minimizing warpage, independent of the absolute dimensions.

The following discussion now refers to a number of methods and method steps. Although the method steps are discussed in specific orders or are illustrated in a flow chart as being performed in a particular order, no order is required unless expressly stated or required because a step is dependent on another step being completed prior to the step being performed.

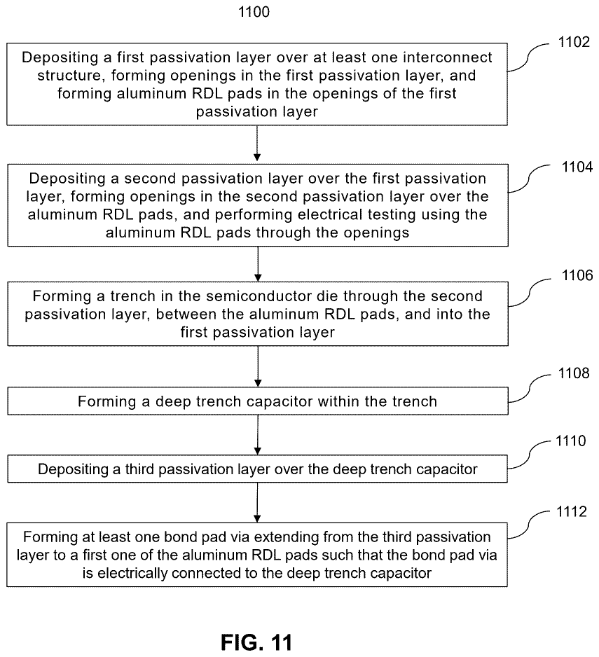

Embodiments are now described in connection with FIG. 11, which illustrates a flow diagram of an example method 1100 for fabricating a semiconductor device 100 according to some embodiments of the present disclosure.

In an embodiment method 1100, step 1102 may include depositing a first passivation layer 120 over one or more interconnect structures 116, forming openings 120a, 120b in the first passivation layer 120, and forming redistribution pads 114a, 114b in the openings 120a, 120b, respectively, of the first passivation layer 120.

In an embodiment method 1100, step 1104 may include depositing the second passivation layer 122 over the first passivation layer 120 and the redistribution pads 114a. 114b, forming openings 122a, 122b in the second passivation layer 122 over the redistribution pads 114a, 114b, performing electrical testing using the redistribution pads 114a, 114b through the openings 122a, 122b in the second passivation layer 122, and filling the openings 122a, 122b in the second passivation layer 122 and planarizing the second passivation layer 122.

In an embodiment method 1100, step 1106 may include forming a trench 902 in the semiconductor die 104 through the second passivation layer 122, between the redistribution pads 114a, 114b, and into the first passivation layer 120. Forming the trench 902 in the semiconductor die 104 may include using lithography and etching techniques. Forming the trench 902 in the semiconductor die 104 may include forming the trench 902 through and beyond the first passivation layer 120.

In an embodiment method 1100, step 1108 includes forming a deep trench capacitor 126 within the trench 902 by depositing a first electrode layer 304a, a dielectric layer 306 over the first electrode layer 304a, and a second electrode layer 308a over the dielectric layer 306. Step 1108 may include depositing a dielectric liner 302 within the trench before depositing the first electrode layer 304a. Step 1108 may include filling a central gap 128 in the deep trench capacitor 126 with a dielectric material. Step 1108 may include performing planarization of the deep trench capacitor 126 by chemical mechanical planarization or any appropriate flattening process. Step 1108 may include electrically connecting at least one of the first electrode layer 304a and the second electrode layer 308a to an adjacent trench capacitor 132.

In an embodiment method 1100, step 1110 may include depositing a third passivation layer 124 over the deep trench capacitor 126. Step 1110 may include forming or placing a long bonding film 138 over the third passivation layer 124.

In an embodiment method 1100, step 1112 may include forming at least a first bond pad via 110 extending from the third passivation layer 124 to a first one of the redistribution pads 114a, 114b such that the bond pad via 110 is electrically connected to the deep trench capacitor 126. Forming the BPV 110 may include forming a cavity 904a in the third passivation layer 124 and the long bonding film 138 and depositing the BPV 110 in the cavity 904a, for example, by depositing a barrier layer, performing copper plating, and planarizing the remaining surface.

The various embodiments disclosed herein may provide various advantages and improvements. For instance, the integration of one or more deep trench capacitors with different configurations enhances capacitance density while optimizing the overall footprint of the semiconductor die, allowing for more compact and efficient designs. Additionally, the ability to directly connect capacitors to top metal conductive pads facilitates improved electrical performance by reducing parasitic resistance and inductance, which may be useful for high-frequency applications. The use of advanced materials and deposition techniques further enables precise control over dielectric thickness and capacitance values, enhancing reliability and performance. Moreover, these designs allow for flexible circuit architectures that can be tailored to specific application requirements, thereby supporting a wide range of electronic devices and systems.

Embodiments of the present disclosure relate to a semiconductor device 100 comprising: a first passivation layer 120; aluminum redistribution layer (RDL) pads 114a, 114b; a second passivation layer 122 over the first passivation layer 120; a deep trench capacitor 126 extending from the second passivation layer 122, between the redistribution pads 114a, 114b, and into the first passivation layer 120, wherein the deep trench capacitor 126 comprises a first electrode layer 304a, a dielectric layer 306 over the first electrode layer 304a, and a second electrode layer 308a over the dielectric layer 306; a third passivation layer 124 over the deep trench capacitor 126; and at least one bond pad via (BPV) 110 extending from the third passivation layer 124 to a first one of the redistribution pads 114a, 114b, wherein the BPV 110 is electrically connected to the deep trench capacitor 126.

In an embodiment, at least one of the first electrode layer 304a and the second electrode layer 308a may be electrically connected to an adjacent deep trench capacitor 132. In an embodiment, the deep trench capacitor 126 extends vertically downward to a first depth and the adjacent deep trench capacitor 132 extends vertically downward to a second depth. In an embodiment, the deep trench capacitor 126 extends through and beyond the first passivation layer 120. In an embodiment, the deep trench capacitor extends through and beyond the first passivation layer. In an embodiment, the deep trench capacitor 126 extends into dielectric layers 136 surrounding an interconnect structure 116. In an embodiment, the deep trench capacitor 126 contacts a top metal pad 130a of an interconnect structure 116. In an embodiment, the semiconductor device 100 includes dielectric material filling a central gap 128 in the deep trench capacitor 126, and the second passivation layer 122 comprises the same dielectric material. In an embodiment, the semiconductor device 100 includes a dielectric liner 302 underneath the first electrode layer 304 of the deep trench capacitor and a capping dielectric material layer 310 over the second electrode layer 308. In an embodiment, the semiconductor device 100 includes a long bonding film 138 over the third passivation layer 124, and the at least one BPV 110 extends from the long bonding film 138 to the first one of the redistribution pads 114a, 114b.

With reference to all of the drawings and description above, in an aspect of the invention a method for fabricating a semiconductor device 100 may be provided. The method includes forming a second passivation layer 122 on a semiconductor die 104, the semiconductor die 104 comprising aluminum redistribution layer (RDL) pads 114a, 114b and a first passivation layer 120. The method includes forming a trench 902 in the semiconductor die 104 through the second passivation layer 122, between the redistribution pads 114a, 114b, and into the first passivation layer 120. The method includes forming a deep trench capacitor 126 within the trench 902 by depositing a first electrode layer 304a, a dielectric layer 306 over the first electrode layer 304a, and a second electrode layer 308a over the dielectric layer 306. The method includes forming a third passivation layer 124 over the deep trench capacitor 126. The method includes forming at least one bond pad via (BPV) 110 extending from the third passivation layer 124 to one of the redistribution pads 114a, 114b such that the BPV 110 is electrically connected to the deep trench capacitor 126.

In an embodiment, the method includes depositing the first passivation layer 120 over at least one interconnect structure 116, forming openings 120a, 120b in the first passivation layer 120, and forming the redistribution pads 114a, 114b in the openings 120a, 120b of the first passivation layer 120. In an embodiment, the method includes depositing the second passivation layer 122 over the first passivation layer 120 and the redistribution pads 114a, 114b, forming openings 122a, 122b in the second passivation layer 122 over the redistribution pads 114a, 114b, and performing electrical testing using the redistribution pads 114a, 114b through the openings 122a, 122b in the second passivation layer 122. In an embodiment, the method includes filling the openings 122a, 122b in the second passivation layer 122 and planarizing the second passivation layer 122. In an embodiment, the method includes forming the redistribution pads 114a, 114b such that the redistribution pads 114a, 114b are positioned over the first passivation layer 120 and extend through the first passivation layer 120. In an embodiment, the method includes forming the redistribution pads 114a, 114b such that the redistribution pads 114a, 114b contact top metal pads 130a, 130b of interconnect structures 116, wherein the interconnect structures 116 electrically connect the top metal pads 130a, 130b to transistors 134 formed on a substrate 108. In an embodiment, the method includes forming an adjacent deep trench capacitor 132 such that at least one of the first electrode layer 304 and the second electrode layer 308 is electrically connected to the adjacent deep trench capacitor 132. In an embodiment, forming the trench 902 in the semiconductor die 104 comprises forming the trench 902 through and beyond the first passivation layer 120.

Embodiments of the present disclosure relate to a semiconductor device 100 comprising: a plurality of longitudinal trench capacitors 1004, each longitudinal trench capacitor extending from a second passivation layer 122 between respective redistribution layer (RDL) pads and into a first passivation layer 120; a plurality of horizontal trench capacitors 1002; wherein a difference between a total length of all of the longitudinal trench capacitors 1004 and a total length of all the horizontal trench capacitors 1002 is less than 25% normalized.

In an embodiment, at least one longitudinal trench capacitor is electrically connected to at least one horizontal trench capacitor. In an embodiment, the semiconductor device includes a plurality of oblique trench capacitors.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first passivation layer;
redistribution pads over the first passivation layer and extending into a recess of the redistribution pads;
a second passivation layer over the first passivation layer;
a deep trench capacitor extending from the second passivation layer, between the redistribution pads, and into the first passivation layer, wherein the deep trench capacitor comprises a first electrode layer, a dielectric layer over the first electrode layer, and a second electrode layer over the dielectric layer;
a third passivation layer over the deep trench capacitor; and
at least one bond pad via (BPV) extending from the third passivation layer to a first one of the redistribution pads, wherein the at least one BPV is electrically connected to the deep trench capacitor.

2. The semiconductor device of claim 1, wherein at least one of the first electrode layer and the second electrode layer is electrically connected to an adjacent deep trench capacitor.

3. The semiconductor device of claim 2, wherein the deep trench capacitor extends vertically downward to a first depth and the adjacent deep trench capacitor extends vertically downward to a second depth.

4. The semiconductor device of claim 1, wherein the deep trench capacitor extends through and beyond the first passivation layer.

5. The semiconductor device of claim 4, wherein the deep trench capacitor extends into dielectric layers surrounding an interconnect structure.

6. The semiconductor device of claim 1, wherein the deep trench capacitor contacts a top metal pad of an interconnect structure.

7. The semiconductor device of claim 1, comprising a dielectric material filling a trench of the deep trench capacitor, wherein the second passivation layer comprises the same dielectric material.

8. The semiconductor device of claim 1, comprising a dielectric liner underneath the first electrode layer of the deep trench capacitor and a capping dielectric material layer over the second electrode layer.

9. The semiconductor device of claim 1, comprising a long bonding film over the third passivation layer, wherein the at least one BPV extends from the long bonding film to the first one of the redistribution pads.

10. A method for fabricating a semiconductor device, the method comprising:
forming a second passivation layer on a semiconductor die, the semiconductor die comprising redistribution pads and a first passivation layer;
forming a trench in the semiconductor die through the second passivation layer, between the redistribution pads, and into the first passivation layer;
forming a deep trench capacitor within the trench by depositing a first electrode layer, a dielectric layer over the first electrode layer, and a second electrode layer over the dielectric layer;
forming a third passivation layer over the deep trench capacitor; and
forming at least one bond pad via (BPV) extending from the third passivation layer to a first one of the redistribution pads such that the BPV is electrically connected to the deep trench capacitor.

11. The method of claim 10, comprising depositing the first passivation layer over at least one interconnect structure, forming openings in the first passivation layer, and forming the redistribution pads in the openings of the first passivation layer.

12. The method of claim 10, comprising depositing the second passivation layer over the first passivation layer and the redistribution pads, forming openings in the second passivation layer over the redistribution pads, and performing electrical testing using the redistribution pads through the openings in the second passivation layer.

13. The method of claim 12, comprising filling the openings in the second passivation layer and planarizing the second passivation layer.

14. The method of claim 10, comprising forming the redistribution pads such that the redistribution pads are positioned over the first passivation layer and extend through the first passivation layer.

15. The method of claim 10, comprising forming the redistribution pads such that the redistribution pads contact top metal pads of interconnect structures, wherein the interconnect structures electrically connect the top metal pads to transistors formed on a substrate.

16. The method of claim 10, comprising forming an adjacent deep trench capacitor such that at least one of the first electrode layer and the second electrode layer is electrically connected to the adjacent deep trench capacitor.

17. The method of claim 10, wherein forming the trench in the semiconductor die comprises forming the trench through and beyond the first passivation layer.

18. A semiconductor device comprising:
a plurality of longitudinal trench capacitors, each longitudinal trench capacitor extending from a second passivation layer, between respective redistribution pads, and into a first passivation layer;
a plurality of horizontal trench capacitors;
wherein a difference between a total length of all of the longitudinal trench capacitors and a total length of all the plurality of horizontal trench capacitors is less than 25% normalized.

19. The semiconductor device of claim 18, wherein at least one longitudinal trench capacitor is electrically connected to at least one horizontal trench capacitor.

20. The semiconductor device of claim 18, comprising a plurality of oblique trench capacitors.
